(19) United States
(12) Patent Application Publication
(10) Pub. No.: US 2026/0011356 A1
(43) Pub. Date: Jan. 8, 2026

(54) MAGNETIC MEMORY DEVICE

(71) Applicant: Kioxia Corporation, Tokyo (JP)

(72) Inventors: Tian LI, Yokohama Kanagawa (JP); Masatoshi YOSHIKAWA, Tokyo (JP); Toshiya MURAKAMI, Tokyo (JP); Yusuke HIGASHI, Zushi Kanagawa (JP); Kensuke OTA, Yokohama Kanagawa (JP); Yoshiaki ASAO, Kawasaki Kanagawa (JP)

(73) Assignee: Kioxia Corporation, Tokyo (JP)

(21) Appl. No.: 19/329,953

(22) Filed: Sep. 16, 2025

Related U.S. Application Data
(63) Continuation of application No. PCT/JP2024/019774, filed on May 29, 2024.

(30) Foreign Application Priority Data
Apr. 4, 2023 (JP) 2023-060877

(51) Int. Cl. G11C 11/16; G11C 5/06; G11C 5/08; H10B 61/00; H10N 50/10; H10N 50/80

(52) U.S. Cl. CPC G11C 11/1675; G11C 5/063; G11C 5/08; G11C 11/161; H10B 61/20; H10N 50/10; H10N 50/80

(57) ABSTRACT

According to one embodiment, a magnetic memory device includes: a first conductor layer extending in a first direction; a second conductor layer extending in the first direction and arranged with the first conductor layer in a second direction intersecting the first direction; a first magnetoresistance effect element electrically connected to the first conductor layer; a second magnetoresistance effect element electrically connected to the second conductor layer; and a third conductor layer extending in the second direction and in contact with the first magnetoresistance effect element. In a write operation of writing data to the first magnetoresistance effect element, a first current is applied to the first conductor layer, a second current is applied to the second conductor layer, and a third current is applied to the third conductor layer independently of the first current and the second current.

### CROSS-REFERENCE TO RELATED APPLICATION

This application is a Continuation Application of PCT Application No. PCT/JP2024/019774, filed May 29, 2024 and based upon and claiming the benefit of priority from Japanese Patent Application No. 2023-060877, filed Apr. 4, 2023, the entire contents of all of which are incorporated herein by reference.

### FIELD

Embodiments described herein relate generally to a magnetic memory device.

### BACKGROUND

A magnetic memory device using a magnetoresistance effect element as a storage element is known. Various methods have been proposed as a method for writing data in a magnetoresistance effect element. For example, a method using spin orbit torque is known as a method of writing data without directly flowing a current to a magnetoresistance effect element.

### BRIEF DESCRIPTION OF THE DRAWINGS

FIG. 1 is a block diagram illustrating an example of a configuration of a magnetic memory device according to a first embodiment.

FIG. 2 is a circuit diagram illustrating an example of a circuit configuration of a memory cell array according to the first embodiment.

FIG. 3 is a cross-sectional view illustrating an example of a cross-sectional structure of a portion of a memory string according to the first embodiment.

FIG. 4 is a diagram illustrating an example of a voltage applied to the memory cell array in a first example of a write operation in the magnetic memory device according to the first embodiment.

FIG. 5 is a diagram illustrating an example of a current and a magnetic field applied to the memory cell array in the first example of the write operation in the magnetic memory device according to the first embodiment.

FIG. 6 is a diagram illustrating an example of a voltage applied to the memory cell array in a second example of the write operation in the magnetic memory device according to the first embodiment.

FIG. 7 is a diagram illustrating an example of a current and a magnetic field applied to the memory cell array in the second example of the write operation in the magnetic memory device according to the first embodiment.

FIG. 8 is a diagram showing a first application example of a timing of applying a current to be applied in the write operation of the magnetic memory device in the first embodiment.

FIG. 9 is a diagram showing a second application example of the timing of applying a current to be applied in the write operation of the magnetic memory device in the first embodiment.

FIG. 10 is a diagram showing a third application example of the timing of applying a current to be applied in the write operation of the magnetic memory device in the first embodiment.

FIG. 11 is a diagram showing a fourth application example of the timing of applying a current to be applied in the write operation of the magnetic memory device in the first embodiment.

FIG. 12 is a diagram showing a fifth application example of the timing of applying a current to be applied in the write operation of the magnetic memory device in the first embodiment.

FIG. 13 is a diagram showing a sixth application example of the timing of applying a current to be applied in the write operation of the magnetic memory device in the first embodiment.

FIG. 14 is a circuit diagram illustrating an example of a circuit configuration of a memory cell array according to a second embodiment.

FIG. 15 is a cross-sectional view illustrating an example of a cross-sectional structure of a portion of the memory cell array according to a second embodiment.

FIG. 16 is a diagram illustrating an example of a voltage to be applied to the memory cell array in a first example of a write operation in the magnetic memory device according to the second embodiment.

FIG. 17 is a diagram illustrating an example of a current and a magnetic field to be applied to the memory cell array in the first example of the write operation in the magnetic memory device according to the second embodiment.

FIG. 18 is a diagram illustrating an example of a voltage to be applied to the memory cell array in a second example of the write operation in the magnetic memory device according to the second embodiment.

FIG. 19 is a diagram illustrating an example of a current and a magnetic field to be applied to the memory cell array in the second example of the write operation in the magnetic memory device according to the second embodiment.

### DETAILED DESCRIPTION

In general, according to one embodiment, a magnetic memory device includes: a first conductor layer extending in a first direction; a second conductor layer extending in the first direction and arranged with the first conductor layer in a second direction intersecting the first direction; a first magnetoresistance effect element electrically connected to the first conductor layer; a second magnetoresistance effect element electrically connected to the second conductor layer; and a third conductor layer extending in the second direction and in contact with the first magnetoresistance effect element. In a write operation of writing data to the first magnetoresistance effect element, a first current is applied to the first conductor layer, a second current is applied to the second conductor layer, and a third current is applied to the third conductor layer independently of the first current and the second current.

Hereinafter, some embodiments will be described with reference to the drawings. Note that, in the following description, components having the same function and configuration are denoted by the same reference numerals. In addition, in a case where a plurality of components having a common reference sign is distinguished, the common reference sign is added with a suffix to be distinguished. Note that, in a case where a plurality of components does not need to be particularly distinguished, only common reference numerals are attached to the plurality of components, and no suffix is attached thereto. The suffix is not limited to a subscript or a superscript, and includes, for example, a lower case alphabet, a symbol, an index meaning an array, and the like added to the end of the reference numeral.

In the present specification, the magnetic memory device is, for example, a magnetoresistance random access memory (MRAM). The magnetic memory device includes a magnetoresistance effect element as a storage element. The magnetoresistance effect element is a resistance change element having a magnetoresistance effect by a magnetic tunnel junction (MTJ). This magnetoresistance effect element is also referred to as an MTJ element.

### 1. First Embodiment

A magnetic memory device according to a first embodiment will be described.

### 1.1 Configuration

First, a configuration of the magnetic memory device according to the first embodiment will be described.

### 1.1.1 Magnetic Memory Device

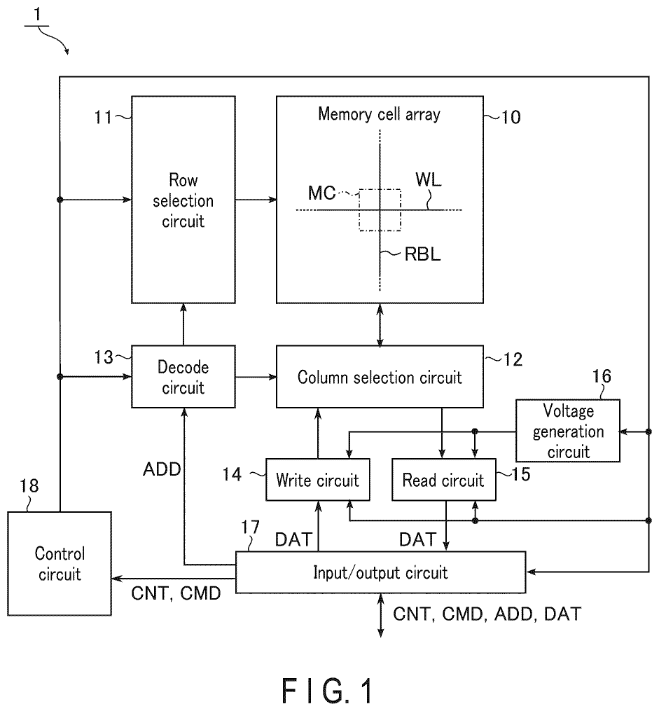

FIG. 1 is a block diagram illustrating an example of a configuration of a magnetic memory device according to a first embodiment. The magnetic memory device 1 includes a memory cell array 10, a row selection circuit 11, a column selection circuit 12, a decode circuit 13, a write circuit 14, a read circuit 15, a voltage generation circuit 16, an input/output circuit 17, and a control circuit 18.

The memory cell array 10 is a data storage unit in the magnetic memory device 1. The memory cell array 10 includes a plurality of memory cells MC. Each of the plurality of memory cells MC is associated with a set of a row and a column. The memory cells MC in the same row are associated with the same word line WL. The memory cells MC in the same column are associated with the same read bit line RBL.

The row selection circuit 11 is a circuit that selects a row of the memory cell array 10. The row selection circuit 11 is connected to the memory cell array 10 via word lines WL. A decoded result (row address) of an address ADD from the decode circuit 13 is supplied to the row selection circuit 11. The row selection circuit 11 selects a word line WL corresponding to a row based on the decoded result of the address ADD. Hereinafter, a word line WL that is selected is referred to as a selected word line WL. The word lines WL other than the selected word line WL are referred to as unselected word lines WL.

The column selection circuit 12 is a circuit that selects a column of the memory cell array 10. The column selection circuit 12 is connected to the memory cell array 10 via read bit lines RBL. The decoded result (column address) of the address ADD from the decode circuit 13 is supplied to the column selection circuit 12. The column selection circuit 12 selects a read bit line RBL corresponding to a column based on the decoded result of the address ADD. Hereinafter, a read bit line RBL that is selected is referred to as a selected bit line RBL. The read bit lines RBL other than the selected bit line RBL are referred to as unselected bit lines RBL.

The decode circuit 13 is a decoder that decodes the address ADD from the input/output circuit 17. The decode circuit 13 supplies a decoded result of the address ADD to the row selection circuit 11 and the column selection circuit 12. The address ADD includes a column address and a row address.

The write circuit 14 includes, for example, a write driver (not illustrated). The write circuit 14 writes data to the memory cell MC.

The read circuit 15 includes, for example, a sense amplifier (not illustrated). The read circuit 15 reads data from the memory cell MC.

The voltage generation circuit 16 generates voltages for various operations of the memory cell array 10 using a power supply voltage provided from the outside (not illustrated) of the magnetic memory device 1. For example, the voltage generation circuit 16 generates various voltages necessary for the write operation and outputs the voltages to the write circuit 14. Furthermore, for example, the voltage generation circuit 16 generates various voltages required at the time of the read operation and outputs the voltages to the read circuit 15.

The input/output circuit 17 manages communication with the outside of the magnetic memory device 1. The input/output circuit 17 transfers the address ADD from the outside of the magnetic memory device 1 to the decode circuit 13. The input/output circuit 17 transfers a command CMD from the outside of the magnetic memory device 1 to the control circuit 18. The input/output circuit 17 transmits and receives various control signals CNT between the outside of the magnetic memory device 1 and the control circuit 18. The input/output circuit 17 transfers data DAT from the outside of the magnetic memory device 1 to the write circuit 14, and outputs the data DAT transferred from the read circuit 15 to the outside of the magnetic memory device 1.

The control circuit 18 includes, for example, a processor such as a central processing unit (CPU), a read only memory (ROM), and a random access memory (RAM). The control circuit 18 controls operations of the row selection circuit 11, the column selection circuit 12, the decode circuit 13, the write circuit 14, the read circuit 15, the voltage generation circuit 16, and the input/output circuit 17 in the magnetic memory device 1 based on the control signal CNT and the command CMD.

### 1.1.2 Memory Cell Array

Next, a configuration of a memory cell array of the magnetic memory device according to the first embodiment will be described.

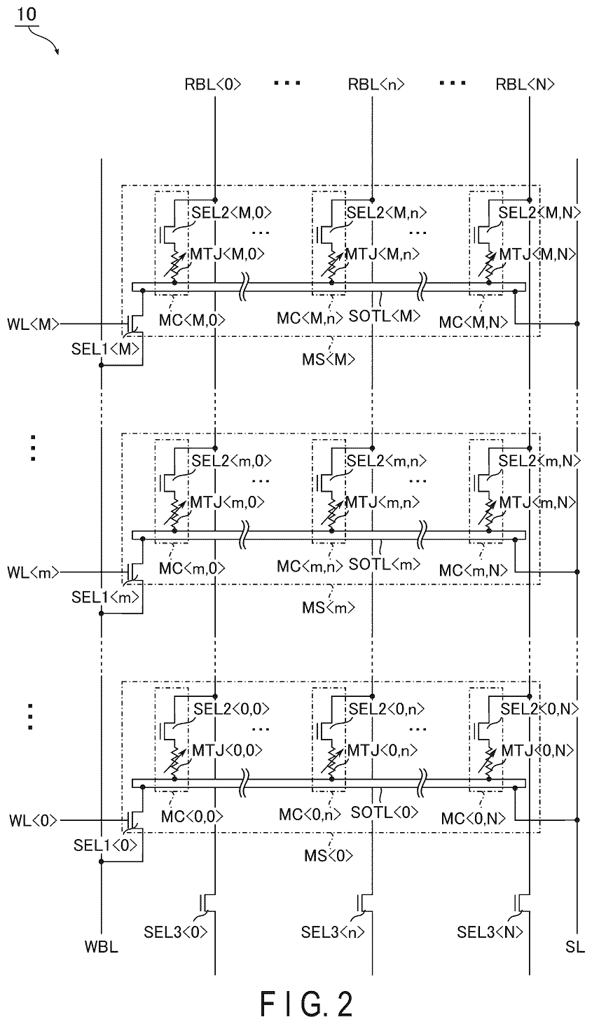

FIG. 2 is a circuit diagram illustrating an example of a circuit configuration of the memory cell array according to the first embodiment. In FIG. 2, various components are classified and shown by suffix including an index (“< >”).

The memory cell array 10 includes a plurality of word lines WL, a plurality of read bit lines RBL, a write bit line WBL, a source line SL, and a plurality of memory strings MS. The memory cell array 10 includes a plurality of switching elements SEL3. The plurality of word lines WL include (M+1) word lines WL<0>, . . . , WL<m>, . . . , and WL<M>. M is an integer of 2 or more (0<m<M). In the example of FIG. 2, a case where M is an integer of 2 or more has been described, but the present invention is not limited thereto. For example, M may be 0 or 1. The plurality of read bit lines RBL includes (N+1) read bit lines RBL<0>, . . . , RBL<n>, . . . , and RBL<N>. N is an integer of 2 or more (0<n<N). The plurality of switching elements SEL3 includes (N+1) switching elements SEL3<0>, . . . , and SEL3<N>. The plurality of memory strings MS includes (M+1) memory strings MS<0>, . . . , MS<m>, . . . , and MS<M>. The memory strings MS<0> to MS<M> are associated with the word lines WL<0> to WL<M>, respectively. Each of the memory strings MS<0> to MS<M> has a same configuration. Hereinafter, the memory string MS<m> will be described as an example.

The memory string MS<m> includes a switching element SEL1<m>, a wiring SOTL<m>, and (N+1) memory cells MC<m, 0>, . . . , MC<m, n>, . . . , and MC<m, N>.

The switching element SEL1<m> is a three-terminal switching element such as a MOSFET. Specifically, the switching element SEL1<m> has a first end connected to the wiring SOTL<m>, a second end connected to the write bit line WBL, and a control end connected to the word line WL<m>.

The wiring SOTL<m> has a first end connected to the first end of the switching element SEL1<m>, a second end connected to the source line SL, and a central portion between both ends. The (N+1) memory cells MC<m, 0>, . . . , MC<m, n>, . . . , and MC<m, N> are connected to the central portion of the wiring SOTL<m> while being separated from each other. Hereinafter, a portion connected to any one of the memory cells MC<m, 0> to MC<m, N> in the central portion of the wiring SOTL<m> is also referred to as a “cell portion”. In the central portion of the wiring SOTL<m>, a portion between two adjacent cell portions is also referred to as a “wiring portion”. Each cell portion of the wiring SOTL<m> has a first end connected to the write bit line WBL via the switching element SEL1<m> and a second end connected to the source line SL.

The memory cells MC<m, 0> to MC<m, N> are connected to the read bit lines RBL<0> to RBL<N>, respectively. Each of the memory cells MC<m, 0> to MC<m, N> has the same configuration. Hereinafter, the memory cell MC<m, n> will be described as an example.

The memory cell MC<m, n> includes a cell portion corresponding to the memory cell MC<m, n> in the wiring SOTL<m>, a switching element SEL2<m, n>, and a magnetoresistance effect element MTJ<m, n>.

The switching element SEL2<m, n> is, for example, a three-terminal switching element such as a MOSFET. The switching element SEL2<m, n> has a first end connected to the magnetoresistance effect element MTJ<m, n>, a second end connected to the read bit line RBL<n>, and a control end.

The magnetoresistance effect element MTJ<m, n> connects the switching element SEL2<m, n> and a cell portion of the wiring SOTL<m> corresponding to the memory cell MC<m, n> in series. The magnetoresistance effect element MTJ<m, n> is a resistance change element. The magnetoresistance effect element MTJ<m, n> functions as a storage element that stores data in a nonvolatile manner by a change in its resistance state.

As described above, each memory string MS includes (N+1) memory cells MC connected to one wiring SOTL. Therefore, the memory cell array 10 includes (M+1) memory strings MS, and thus includes (M+1)×(N+1) memory cells MC<0, 0>, . . . , MC<0, n>, . . . , MC<0, N>, . . . , MC<m, 0>, . . . , MC<m, n>, . . . , MC<m, N>, . . . , MC<M, 0>, . . . , MC<M, n>, . . . , and MC<M, N>.

Each of the switching elements SEL3<0> to SEL3<N> is, for example, a three-terminal switching element such as a MOSFET. Each of the switching elements SEL3<0> to SEL3<N> has the same configuration. Hereinafter, the switching element SEL3<n> will be described as an example. The switching element SEL3<n> is provided on a path of the read bit line RBL<n>. The (M+1) switching elements SEL2<0, n> to SEL2<M, n> are commonly connected to a first end of the switching element SEL3<n> via the read bit line RBL<n>. As a result, the switching element SEL3<n> can control whether to transfer the voltage applied to the read bit line RBL<n> to the (M+1) switching elements SEL2<0, n> to SEL2<M, n>.

### 1.1.3 Memory String

Next, a configuration of a memory string of the magnetic memory device according to the first embodiment will be described. Hereinafter, a plane parallel to a surface of a substrate on which the memory cell array 10 is provided is referred to as an XY plane. A direction in which the memory cell array 10 is provided with respect to the substrate surface is defined as a Z direction or an upward direction. The directions intersecting each other in the XY plane are defined as an X direction and a Y direction.

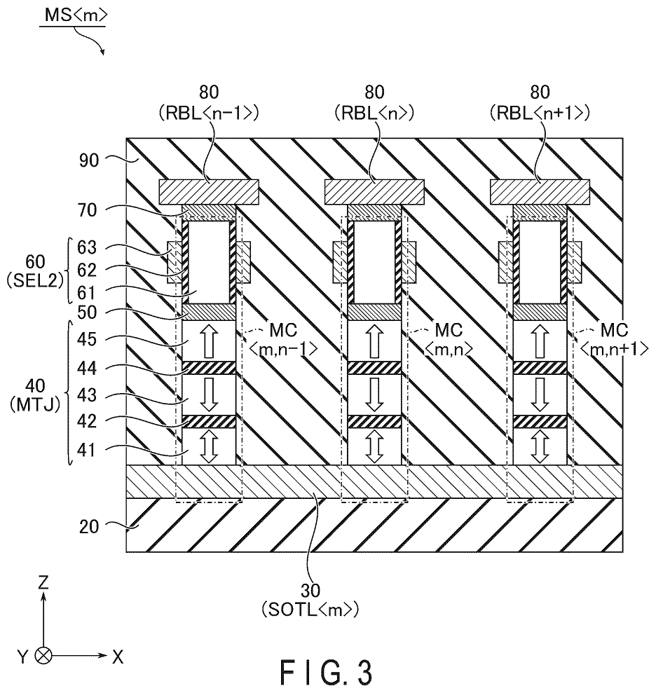

FIG. 3 is a cross-sectional view illustrating an example of a cross-sectional structure of a portion of the memory string according to the first embodiment. As shown in FIG. 3, the memory string MS<m> includes a conductor layer 30, a plurality of element layers 40, a plurality of conductor layers 50, a plurality of element layers 60, a plurality of conductor layers 70, and a plurality of conductor layers 80. FIG. 3 illustrates, as an example, a part of the wiring SOTL<m> and three memory cells MC<m, n−1>, MC<m, n>, and MC<m, n+1> connected to the part of the wiring SOTL<m> among the memory strings MS<m>.

### (Overall Structure)

First, the overall structure of the memory string MS will be described.

An insulator layer 20 is provided above the substrate (not shown). The conductor layer 30 is provided on an upper surface of the insulator layer 20. The conductor layer 30 extends in the X direction. The conductor layer 30 is used as a wiring SOTL<m>. A portion of the conductor layer 30 overlapping the element layer 40 as viewed in the Z direction is used as a cell portion. A portion of the conductor layer 30 that does not overlap the element layer 40 as viewed in the Z direction is used as a wiring portion.

The conductor layer 30 is a continuous film containing nonmagnetic and conductive heavy metals. The conductor layer 30 contains at least one element selected from, for example, tantalum (Ta), tungsten (W), rhenium (Re), ruthenium (Ru), rhodium (Rh), palladium (Pd), silver (Ag), copper (Cu), osmium (Os), iridium (Ir), platinum (Pt), gold (Au), manganese (Mn), lead (Pb), bismuth (Bi), antimony (Sb), tellurium (Te), selenium (Se), and polonium (Po) as a heavy metal. The element contained in the conductor layer 30 as a heavy metal may contain an oxide, a nitride, or a sulfide. In a case where tungsten (W) or tantalum (Ta) is contained, the structure of the element is preferably a β structure. For the conductor layer 30, a conductive oxide such as ruthenium oxide (RuO₂) or iridium oxide (IrO₂) may be used. For the conductor layer 30, a dichalcogenide transition metal having a two-dimensional layered structure such as WTe₂, WS₂, or WSe₂ may be used. The conductor layer 30 may be constituted by a single layer containing the above-described material, or may be configured by stacking a plurality of layers containing the above-described material. The conductor layer 30 generates spin mainly due to the spin-Hall effect by a current flowing inside. In addition, spin torque due to a spin splitter effect, spin torque due to a Rashba effect, and the like may be generated. These spin torques are collectively referred to as spin orbit torque (SOT). The spin orbit torque acts on a portion of the element layer 40 in contact with the conductor layer 30.

A plurality of element layers 40 is provided on the upper surface of the conductor layer 30. Each of the plurality of element layers 40 has a columnar shape extending in the Z direction. Each of the plurality of element layers 40 is used as a magnetoresistance effect element MTJ. Details of the configuration of the element layer 40 will be described later.

The conductor layer 50 is provided on an upper surface of each of the plurality of element layers 40. Each of the plurality of conductor layers 50 has a columnar shape extending in the Z direction. Each of the plurality of conductor layers 50 is used as an electrode for electrically connecting between the element layer 40 and the element layer 60.

The element layer 60 is provided on an upper surface of each of the plurality of conductor layers 50. Each of the plurality of element layers 60 has a columnar shape extending in the Z direction. Each of the plurality of element layers 60 is used as a three-terminal switching element. Details of the configuration of the element layer 60 will be described later.

The conductor layer 70 is provided on an upper surface of each of the plurality of element layers 60. Each of the plurality of conductor layers 70 has a columnar shape extending in the Z direction. Each of the plurality of conductor layers 70 is used as an electrode for electrically connecting between the element layer 60 and the conductor layer 80.

The conductor layer 80 is provided on an upper surface of each of the plurality of conductor layers 70. Each of the plurality of conductor layers 80 extends in the Y direction. The plurality of conductor layers 80 is arranged in the X direction. Each of the plurality of conductor layers 80 is used as a read bit line RBL.

The element layer 40, the conductor layer 50, the element layer 60, the conductor layer 70, and the conductor layer 80 are covered with an insulator layer 90.

### (Magnetoresistance Effect Element MTJ)

Next, the structure of the magnetoresistance effect element MTJ included in the memory string MS will be described.

Each of the plurality of element layers 40 includes a ferromagnetic layer 41, a nonmagnetic layer 42, a ferromagnetic layer 43, a nonmagnetic layer 44, and a ferromagnetic layer 45. The ferromagnetic layer 41, the nonmagnetic layer 42, the ferromagnetic layer 43, the nonmagnetic layer 44, and the ferromagnetic layer 45 are stacked in this order from the bottom to the top.

The ferromagnetic layer 41 is provided so as to be in contact with the upper surface of the conductor layer 30. The ferromagnetic layer 41 is a conductive film having ferromagnetism. The ferromagnetic layer 41 is used as a storage layer. The ferromagnetic layer 41 has an easy magnetization axis direction in a direction perpendicular to the film surface (Z direction). The spin orbit torque generated in the conductor layer 30 acts on the ferromagnetic layer 41. In a case where a spin orbit torque of a predetermined magnitude acts, the magnetization direction of the ferromagnetic layer 41 is configured to be reversed.

The ferromagnetic layer 41 is generally a ferromagnetic layer using any element selected from cobalt (Co), iron (Fe), and nickel (Ni). A cobalt iron (CoFe) alloy, iron (Fe), cobalt iron boron (CoFeB), iron boron (FeB), cobalt boron (CoB), cobalt iron nickel boron (CoFeNiB), and the like are typical ferromagnetic layers in which perpendicular magnetization occurs. These have a body-centered cubic structure (BCC structure). In addition, examples of an element in place of the boron (B) include phosphorus (P) and carbon (C). The magnetic material such as CoFeB described above generates perpendicular magnetic anisotropy at an interface by being in contact with an oxide having a NaCl (001) structure. A MgO (001)/CoFeB stacked film or the like is typical.

The nonmagnetic layer 42 is provided on an upper surface of the ferromagnetic layer 41. The nonmagnetic layer 42 is an insulating film having nonmagnetism. The nonmagnetic layer 42 is used as a tunnel barrier layer. The nonmagnetic layer 42 is provided between the ferromagnetic layer 41 and the ferromagnetic layer 43, and forms a magnetic tunnel junction together with these two ferromagnetic layers. That is, a magnetoresistance effect occurs at the magnetic tunnel junction portion. In addition, in a case where an initial amorphous layer such as cobalt iron boron (CoFeB) is used for the interface layer of the ferromagnetic layer 41, the nonmagnetic layer 42 functions as a seed material to be a nucleus for growing a crystalline film from the interface with the ferromagnetic layer 41 in the crystallization process of the ferromagnetic layer 41. Similarly, in a case where cobalt iron boron (CoFeB) is used as the interface layer of the ferromagnetic layer 43, the nonmagnetic layer 42 also functions as a seed material for the ferromagnetic layer 43. Here, the initial amorphous layer is a layer that is in an amorphous state immediately after film formation and crystallizes after annealing processing. The nonmagnetic layer 42 has a tetragonal or cubic structure in which a film surface is oriented in a (001) plane. As the oxide used for the nonmagnetic layer 42, for example, magnesium oxide (MgO) is representative. Other examples of the oxide used for the nonmagnetic layer 42 include magnesium aluminum oxide (MgAlOx). Hereinafter, a case where magnesium oxide (MgO) is applied will be described. Magnesium oxide (MgO) has a NaCl structure. When magnesium oxide (MgO) is used for the nonmagnetic layer 42, a (001) interface of magnesium oxide (MgO) and a (001) interface of cobalt iron boron (CoFeB) are matched with each other, and crystal growth is performed by annealing processing. Therefore, the cobalt iron boron (CoFeB) has a body-centered cubic structure oriented in (001).

The ferromagnetic layer 43 is provided on an upper surface of the nonmagnetic layer 42. The ferromagnetic layer 43 is a conductive film having ferromagnetism. The ferromagnetic layer 43 is used as a reference layer. The ferromagnetic layer 43 has an easy magnetization axis direction in a direction perpendicular to the film surface (Z direction). The magnetization direction of the ferromagnetic layer 43 is fixed. Note that “the magnetization direction is fixed” means that the magnetization direction does not change by a torque of a magnitude that can reverse the magnetization direction of the ferromagnetic layer 41. In the example of FIG. 3, the magnetization direction of the ferromagnetic layer 43 faces the direction of the ferromagnetic layer 41. Usually, the ferromagnetic layer 43 includes an interface layer. As an interface layer of the ferromagnetic layer 43, an initial amorphous layer such as cobalt iron boron (CoFeB) is used. Further, an auxiliary ferromagnetic layer is provided so as to be in contact with a surface of the cobalt iron boron (CoFeB) layer opposite to a surface in contact with the magnesium oxide (MgO) layer. The auxiliary ferromagnetic layer includes, for example, at least one alloy film selected from cobalt platinum (CoPt), cobalt nickel (CoNi), and cobalt palladium (CoPd). As the auxiliary ferromagnetic layer, a stacked film such as a Co/Pt stacked film or a Co/Pd stacked film can also be used. The cobalt iron boron (CoFeB) layer serving as an initial amorphous layer is used by being stacked with the CoPt, CoPd, a Co/Pt stacked film, a Co/Pd stacked film, or the like. In this case, in the interface layer of the ferromagnetic layer 43, for example, in the above-mentioned CoFeB layer, MgO oriented in (001) is formed closer to the nonmagnetic layer 42 than in the other layers.

The nonmagnetic layer 44 is provided on an upper surface of the ferromagnetic layer 43. The nonmagnetic layer 44 is a nonmagnetic conductive film. The nonmagnetic layer 44 is used as a spacer layer. The nonmagnetic layer 44 is made of, for example, an element selected from ruthenium (Ru), osmium (Os), rhodium (Rh), iridium (Ir), and chromium (Cr), or an alloy thereof.

The ferromagnetic layer 45 is provided on an upper surface of the nonmagnetic layer 44. The ferromagnetic layer 45 is a conductive film having ferromagnetism. The ferromagnetic layer 45 is used as a shift cancelling layer. The ferromagnetic layer 45 has an easy magnetization axis direction in a direction perpendicular to the film surface (Z direction). The ferromagnetic layer 45 includes, for example, at least one alloy layer selected from cobalt platinum (CoPt), cobalt palladium (CoPd), cobalt palladium platinum (CoPdPt), and cobalt chromium platinum (CoCrPt). In addition, as the ferromagnetic layer 45, a stacked film such as a Co/Pt stacked film, a Co/Pd stacked film, or a Co/Ni stacked film can also be used.

The ferromagnetic layer 43 and the ferromagnetic layer 45 are antiferromagnetically coupled by the nonmagnetic layer 44. That is, the ferromagnetic layer 43 and the ferromagnetic layer 45 are coupled so as to have magnetization directions antiparallel to each other. Such antiferromagnetic magnetic coupling of the ferromagnetic layer 43, the nonmagnetic layer 44, and the ferromagnetic layer 45 is referred to as synthetic anti-ferromagnetic (SAF) coupling. With the SAF coupled state, the ferromagnetic layer 45 can offset the influence of the leakage magnetic field of the ferromagnetic layer 43 on the change in the magnetization direction of the ferromagnetic layer 41 and reduce the influence of the substantial leakage magnetic field of the ferromagnetic layer 43 on the ferromagnetic layer 41.

The magnetoresistance effect element MTJ can take either a low resistance state or a high resistance state depending on whether the relative relationship between the magnetization directions of the storage layer and the reference layer is parallel or antiparallel. In the magnetic memory device 1, the magnetization direction of the storage layer with respect to the magnetization direction of the reference layer is controlled without flowing a write current to such a magnetoresistance effect element MTJ. Specifically, a writing method using spin orbit torque generated by flowing a current through the wiring SOTL is adopted.

When a write current Ic0 of a certain magnitude flows in the wiring SOTL in the X direction, the relative relationship between the magnetization directions of the storage layer and the reference layer becomes parallel. In this parallel state, the resistance value of the magnetoresistance effect element MTJ is the lowest, and the magnetoresistance effect element MTJ is set to the low resistance state. This low resistance state is called a “P (Parallel) state” and is defined as, for example, a state of data “0”.

In addition, in a case where the write current Ic1 flows in the wiring SOTL in the direction opposite to the write current Ic0, the relative relationship between the magnetization directions of the storage layer and the reference layer becomes antiparallel. In the antiparallel state, the resistance value of the magnetoresistance effect element MTJ is the highest, and the magnetoresistance effect element MTJ is set to the high resistance state. This high resistance state is called an “anti-parallel (AP) state” and is defined as, for example, a state of data “1”.

Note that the manner of specifying the data “1” and the data “0” is not limited to the above-described example. For example, the P state may be defined as data “1”, and the AP state may be defined as data “0”.

### (Switching Element SEL2)

Next, the structure of the switching element SEL2 included in the memory string MS will be described.

The element layer 60 includes a semiconductor film 61, an insulator film 62, and a conductor layer 63. The element layer 60 has, for example, a surrounding gate transistor (SGT) structure.

The semiconductor film 61 is provided at a central portion of the element layer 60 as viewed in the Z direction. The semiconductor film 61 extends in the Z direction and has a lower end in contact with the conductor layer 50 and an upper end in contact with the conductor layer 70. The semiconductor film 61 is used as a current path (channel) of the switching element SEL2. The semiconductor film 61 contains, for example, silicon (Si).

The insulator film 62 covers a side surface of the semiconductor film 61. The insulator film 62 is used as a gate insulating film of the switching element SEL2. The insulator film 62 includes, for example, silicon oxide (SiO₂).

The conductor layer 63 covers a part of a side surface of the insulator film 62. The conductor layer 63 is used as a gate of the switching element SEL2. The conductor layer 63 contains, for example, tungsten (W).

### 1.2 Write Operation

Next, a write operation of the magnetic memory device according to the first embodiment will be described.

### 1.2.1 First Example

First, a first example of the write operation will be described. The first example of the write operation corresponds to a case where the write current Ic0 flows through the wiring SOTL to write the data “0”.

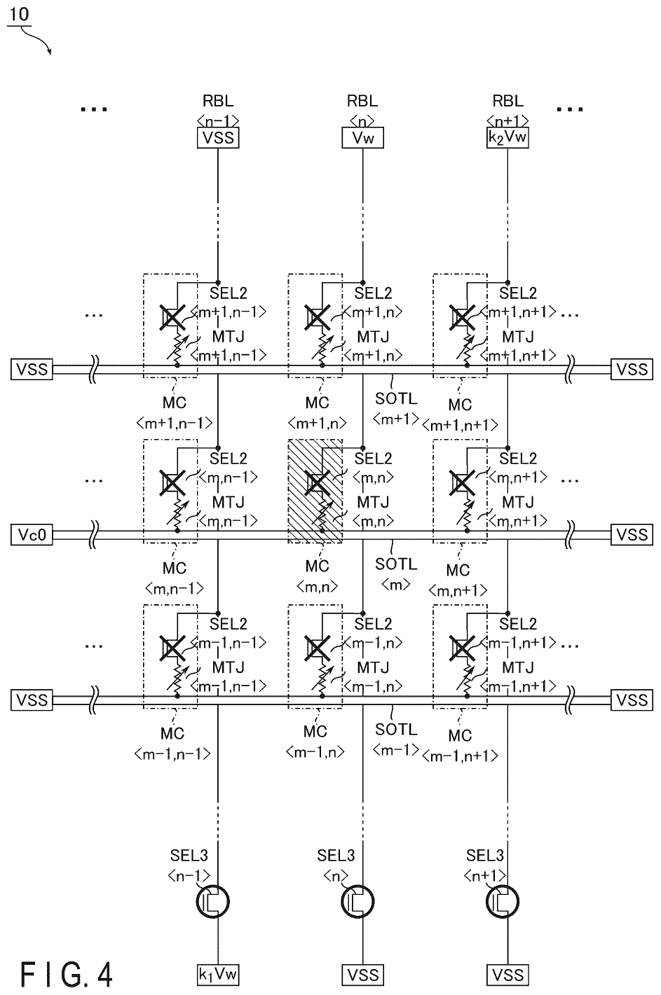

FIG. 4 is a diagram illustrating an example of a voltage applied to the memory cell array in the first example of the write operation in the magnetic memory device according to the first embodiment. FIG. 4 shows an example of voltages applied to three wirings SOTL<m−1>, SOTL<m>, and SOTL<m+1> and three read bit lines RBL<n−1>, RBL<n>, and RBL<n+1> in the memory cell array 10. In FIG. 4, “∘” is attached to each of the switching elements SEL2 and SEL3 in the ON state, and “×” is attached to each of the switching elements SEL2 and SEL3 in the OFF state. In FIG. 4, a memory cell MC<m, n> as a write target (That is, the selected state) is hatched.

When the first example of the write operation is executed for the selected memory cell MC<m, n>, all the switching elements SEL2 are turned off. The switching elements SEL3<n−1>, SEL3<n>, and SEL3<n+1> are turned on. Then, all the other switching elements SEL3 are turned off.

Further, voltages Vc0 and VSS are applied to the first end and the second end of the wiring SOTL<m>, respectively. The voltage VSS is, for example, 0 V. The voltage Vc0 is a voltage for causing a write current Ic0<m> (not illustrated) to flow through the wiring SOTL. Then, the voltage VSS is applied to the first end and the second end of each of the wirings SOTL<m−1> and SOTL<m+1> located on both sides of the wiring SOTL<m>. Although not illustrated in FIG. 4, the voltage VSS is applied to the first end and the second end of each of the other wirings SOTL.

Further, voltages VSS and Vw are applied to the first end and the second end of the selected bit line RBL<n>, respectively. The first end of the selected bit line RBL<n> is an end opposite to the memory cell array 10 with respect to the switching element SEL3<n>. The second end of the selected bit line RBL<n> is an end on the side sandwiching the memory cell array 10 with the switching element SEL3<n>. The voltage Vw is a voltage for supplying a current Iw0<n> (not illustrated) to the selected bit line RBL<n>.

The voltages k₁Vw and VSS are applied to the first end and the second end of the unselected bit line RBL<n−1> located on one of both sides of the selected bit line RBL<n>, respectively. The first end of the unselected bit line RBL<n−1> is an end opposite to the memory cell array 10 with respect to the switching element SEL3<n−1>. The second end of the unselected bit line RBL<n−1> is an end on the side sandwiching the memory cell array 10 with the switching element SEL3<n−1>. The voltage k₁Vw is a voltage k₁ times the voltage Vw (0<k₁<1). The voltage k₁Vw is a voltage for causing the current Iw0<n−1> to flow through the unselected bit line RBL<n−1>.

The voltages VSS and k₂Vw are applied to the first end and the second end of the unselected bit line RBL<n+1> located on the other of both sides of the selected bit line RBL<n>, respectively. The first end of the unselected bit line RBL<n+1> is an end opposite to the memory cell array 10 with respect to the switching element SEL3<n+1>. The second end of the unselected bit line RBL<n+1> is an end on the side sandwiching the memory cell array 10 with the switching element SEL3<n+1>. The voltage k₂Vw is a voltage k₂ times the voltage Vw (0<k₂<1). The voltage k₂Vw is a voltage for causing the current Iw0<n+1> to flow through the unselected bit line RBL<n+1>. Note that k₁ and k₂ may be different from each other or equal to each other.

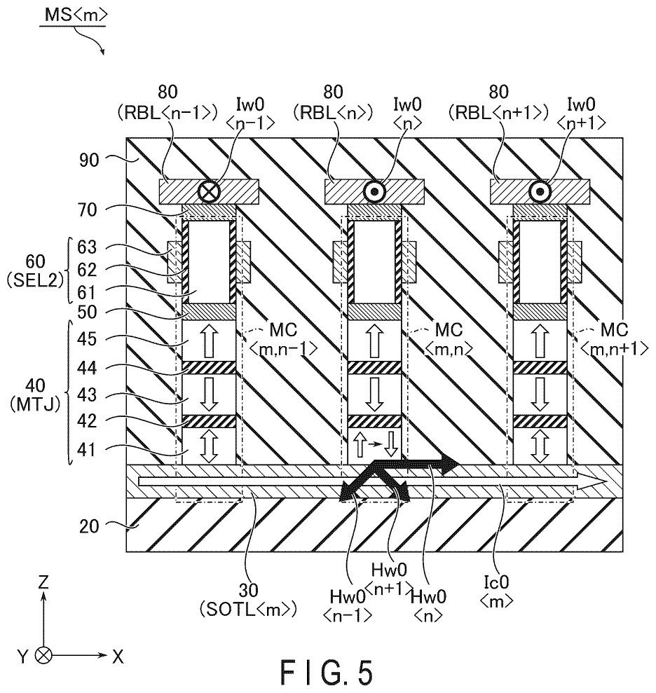

FIG. 5 is a diagram illustrating an example of a current and a magnetic field applied to the memory cell array in the first example of the write operation in the magnetic memory device according to the first embodiment; FIG. 5 illustrates currents Ic0<m>, Iw0<n>, Iw0<n−1>, and Iw0<n+1>, and magnetic fields Hw0<n>, Hw0<n−1>, and Hw0<n+1> generated by the voltages Vc0, Vw, k₁Vw, and k₂Vw illustrated in FIG. 4, respectively, and a change in the magnetization direction in the selected memory cell MC<m, n>.

As described above, the voltages Vc0 and VSS are applied to both ends of the wiring SOTL<m>, respectively. As a result, a write current Ic0<m> flows from the left side of the conductor layer 30 in the drawing to the right side (+X direction in FIG. 5) in the drawing. When the write current Ic0<m> flows in the conductor layer 30, a spin orbit torque for making the magnetization direction of the ferromagnetic layer 41 parallel to the ferromagnetic layer 43 is generated. The spin orbit torque acts on all the ferromagnetic layers 41 in contact with the conductor layer 30.

Further, as described above, the voltages VSS and Vw are applied to both ends of the selected bit line RBL<n>, respectively. Voltages k₁Vw and VSS are applied to both ends of the unselected bit line RBL<n−1>, respectively. The voltages VSS and k₂Vw are applied to both ends of the unselected bit line RBL<n+1>, respectively. As a result, a current Iw0<n> flows in the conductor layer 80 corresponding to the selected bit line RBL<n> from the back side of the page toward the front side of the page (−Y direction in FIG. 5). In the conductor layer 80 corresponding to the unselected bit line RBL<n−1>, a current Iw0<n−1> flows from the front side to the far side (+Y direction in FIG. 5) in the drawing. In the conductor layer 80 corresponding to the selected bit line RBL<n+1>, a current Iw0<n+1> flows from the back side of the page toward the front side of the page (−Y direction in FIG. 5). The currents Iw0<n−1> and Iw0<n+1> are, for example, k₁ times and k₂ times the current Iw0<n>, respectively. That is, the current values of the currents Iw0<n−1> and Iw0<n+1> are smaller than the current value of the current Iw0<n>.

By the currents Iw0<n>, Iw0<n−1>, and Iw0<n+1>, magnetic fields Hw0<n>, Hw0<n−1>, and Hw0<n+1> are applied to the vicinity of the interface between the conductor layer 30 and the ferromagnetic layer 41 corresponding to the selected memory cell MC<m, n>, respectively. The magnetic fields Hw0<n>, Hw0<n−1>, and Hw0<n+1> are respectively applied concentrically around the currents Iw0<n>, Iw0<n−1>, and Iw0<n+1> in a counterclockwise direction with respect to the directions of the currents Iw0<n>, Iw0<n−1>, and Iw0<n+1>.

As a result, in the example of FIG. 5, the magnetic field Hw0<n> applied to the selected memory cell MC<m, n> becomes the direction (+X direction) in which the current Ic0<m> flows. In the example of FIG. 5, the directions of the magnetic fields Hw0<n−1> and Hw0<n+1> applied to the selected memory cell MC<m, n> are inclined in the −Z direction with respect to the direction in which the current Ic0<m> flows. Then, the magnetic fields Hw0<n−1> and Hw0<n+1> applied to the selected memory cells MC<m, n> are applied in directions mutually reinforcing in the −Z direction. Therefore, the combined magnetic field of the magnetic fields Hw0<n>, Hw0<n−1>, and Hw0<n+1> applied to the selected memory cell MC<m, n> becomes a magnetic field having a component in the +X direction and a component in the −Z direction.

The direction of the magnetic field Hw0<n> is determined according to the material constituting the conductor layer 30. Therefore, the direction of the magnetic field Hw0<n> may be opposite to the direction in which the current Ic0<m> flows (−X direction). Furthermore, the direction of the combined magnetic field of the magnetic fields Hw0<n−1> and Hw0<n+1> has a component in the magnetization direction (−Z direction) of the ferromagnetic layer 41 determined by the write operation.

The component in the X direction of the combined magnetic field of the magnetic fields Hw0<n>, Hw0<n−1>, and Hw0<n+1> applied to the selected memory cell MC<m, n> assists the reversal of the magnetization direction of the ferromagnetic layer 41 of the selected memory cell MC<m, n> by the spin orbit torque. The component in the Z direction of the combined magnetic field of the magnetic fields Hw0<n>, Hw0<n−1>, and Hw0<n+1> applied to the selected memory cell MC<m, n> increases the reversal speed of the magnetization direction of the ferromagnetic layer 41 of the selected memory cell MC<m, n> due to the spin orbit torque, and suppresses the frustration in the reversal process. As a result, the magnetization direction of the ferromagnetic layer 41 of the selected memory cell MC<m, n> is reversed in a direction parallel to the magnetization direction of the ferromagnetic layer 43.

By the above operation, the data “0” is written to the selected memory cell MC<m, n>.

### 1.2.2 Second Example

Next, a second example of the write operation will be described. The second example of the write operation corresponds to a case where the write current Ic1 flows through the wiring SOTL to write the data “1”.

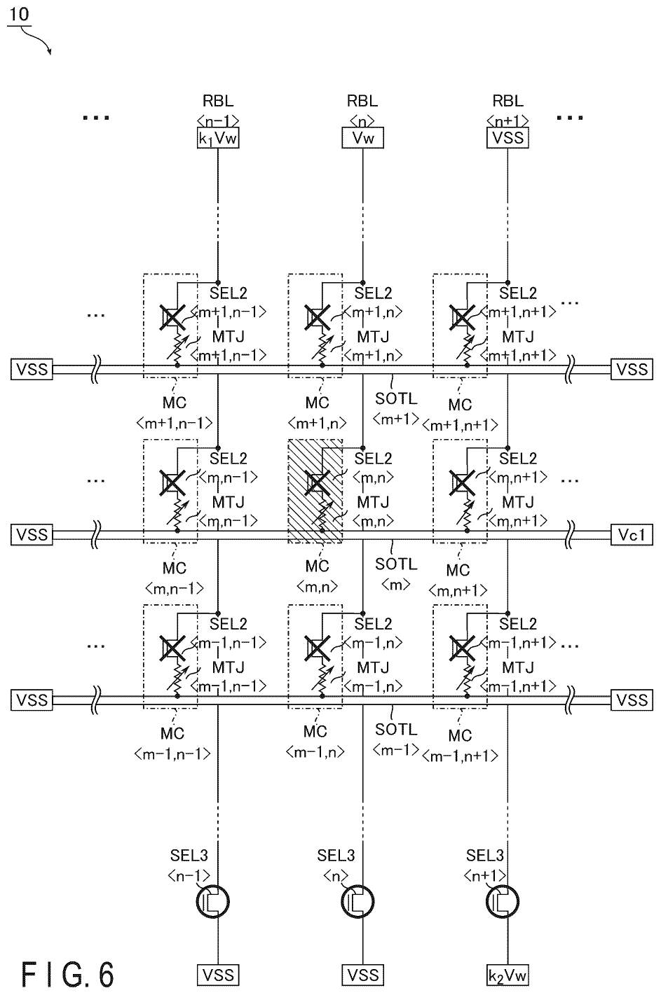

FIG. 6 is a diagram illustrating an example of a voltage applied to the memory cell array in the second example of the write operation in the magnetic memory device according to the first embodiment. FIG. 6 corresponds to FIG. 4 in the first example of the write operation.

When the second example of the write operation is executed for the selected memory cell MC<m, n>, all the switching elements SEL2 are turned off. The switching elements SEL3<n−1>, SEL3<n>, and SEL3<n+1> are turned on. Then, all the other switching elements SEL3 are turned off.

Further, voltages VSS and Vc1 are applied to the first end and the second end of the wiring SOTL<m>, respectively. The voltage Vc1 is a voltage for causing a write current Ic1<m> (not illustrated) to flow through the wiring SOTL. As described above, the polarity of the voltage applied to the wiring SOTL<m> in the second example of the write operation may be reversed from the polarity of the voltage applied to the wiring SOTL<m> in the first example of the write operation, and the magnitude thereof may also be different. Then, the voltage VSS is applied to the first end and the second end of each of the wiring SOTL<m−1> and SOTL<m+1> located on both sides of the wiring SOTL<m>. Although not illustrated in FIG. 6, the voltage VSS is applied to the first end and the second end of each of the other wiring SOTL.

The voltages VSS and Vw are applied to the first end and the second end of the selected bit line RBL<n>, respectively. The voltages VSS and k₁Vw are applied to the first end and the second end of the unselected bit line RBL<n−1>, respectively. The voltages k₂Vw and VSS are applied to the first end and the second end of the unselected bit line RBL<n+1>, respectively. As described above, the voltage applied to the selected bit line RBL<n> in the second example of the write operation is equal to the voltage applied to the selected bit line RBL<n> in the first example of the write operation. On the other hand, the voltages applied to the unselected bit lines RBL<n−1> and RBL<n+1> in the second example of the write operation are inverted in polarity from the voltages applied to the unselected bit lines RBL<n−1> and RBL<n+1> in the first example of the write operation.

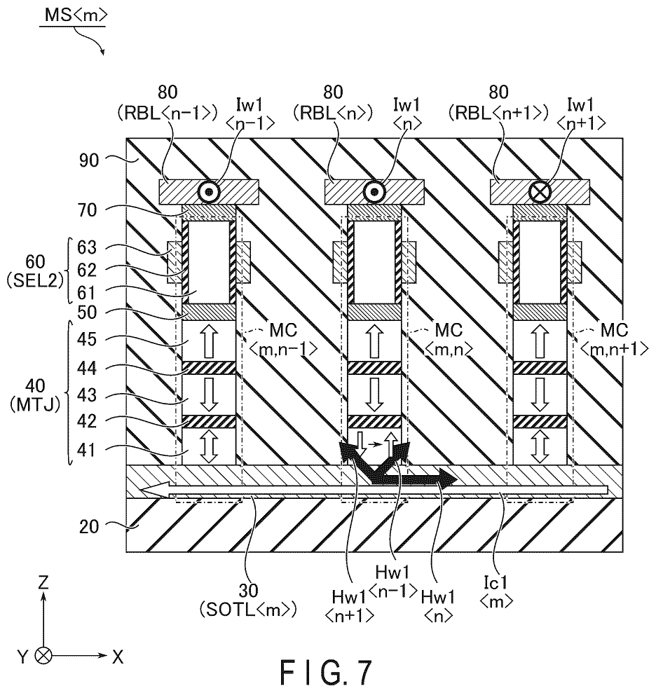

FIG. 7 is a diagram illustrating an example of a current and a magnetic field applied to the memory cell array in the second example of the write operation in the magnetic memory device according to the first embodiment; FIG. 7 corresponds to FIG. 5 in the first example of the write operation.

As described above, the voltages VSS and Vc1 are applied to both ends of the wiring SOTL<m>, respectively. As a result, a write current Ic1<m> flows from the right side of the conductor layer 30 in the drawing to the left side (−X direction in FIG. 7) in the drawing. If the write current Ic1<m> flows in the conductor layer 30, a spin orbit torque for making the magnetization direction of the ferromagnetic layer 41 antiparallel to the ferromagnetic layer 43 is generated. The spin orbit torque acts on all the ferromagnetic layers 41 in contact with the conductor layer 30.

Further, as described above, the voltages VSS and Vw are applied to both ends of the selected bit line RBL<n>, respectively. The voltages VSS and k₁Vw are applied to both ends of the unselected bit line RBL<n−1>, respectively. The voltages k₂Vw and VSS are applied to both ends of the unselected bit line RBL<n+1>, respectively. As a result, a current Iw1<n> flows in the conductor layer 80 corresponding to the selected bit line RBL<n> from the back side of the page toward the front side of the page (−Y direction in FIG. 7). In the conductor layer 80 corresponding to the unselected bit line RBL<n−1>, a current Iw1<n−1> flows from the back side of the page toward the front side of the page (−Y direction in FIG. 7). In the conductor layer 80 corresponding to the selected bit line RBL<n+1>, a current Iw1<n+1> flows from the front side to the far side (+Y direction in FIG. 7). The currents Iw1<n−1> and Iw1<n+1> are, for example, k₁ times and k₂ times the current Iw1<n>, respectively. That is, the current values of the currents Iw1<n−1> and Iw1<n+1> are smaller than the current value of the current Iw1<n>.

The magnetic fields Hw1<n>, Hw1<n−1>, and Hw1<n+1> are applied to the vicinity of the interface between the conductor layer 30 and the ferromagnetic layer 41 corresponding to the selected memory cell MC<m, n> by the currents Iw1<n>, Iw1<n−1>, and Iw1<n+1>, respectively. The direction of the magnetic field Hw1<n> applied to the selected memory cell MC<m, n> is opposite to the direction in which the current Ic1<m> flows (+X direction). The directions of the magnetic fields Hw1<n−1> and Hw1<n+1> applied to the selected memory cell MC<m, n> are inclined in the +Z direction with respect to the direction in which the current Ic1<m> flows. Then, the magnetic fields Hw1<n−1> and Hw1<n+1> applied to the selected memory cells MC<m, n> are applied in directions mutually reinforcing in the +Z direction. Therefore, the combined magnetic field of the magnetic fields Hw1<n>, Hw1<n−1>, and Hw1<n+1> applied to the selected memory cell MC<m, n> becomes a magnetic field having a component in the +X direction and a component in the +Z direction.

Note that the direction of the magnetic field Hw1<n> is determined according to the material constituting the conductor layer 30, similarly to the direction of the magnetic field Hw0<n>. Therefore, the direction of the magnetic field Hw1<n> does not change regardless of the data to be written. In addition, the direction of the combined magnetic field of the magnetic fields Hw1<n−1> and Hw1<n+1> has a component in the magnetization direction (+Z direction) of the ferromagnetic layer 41 determined by the write operation.

The component in the X direction of the combined magnetic field of the magnetic fields Hw1<n>, Hw1<n−1>, and Hw1<n+1> applied to the selected memory cell MC<m, n> assists the reversal of the magnetization direction of the ferromagnetic layer 41 of the selected memory cell MC<m, n> by the spin orbit torque. The component in the Z direction of the combined magnetic field of the magnetic fields Hw1<n>, Hw1<n−1>, and Hw1<n+1> applied to the selected memory cell MC<m, n> increases the reversal speed of the magnetization direction of the ferromagnetic layer 41 of the selected memory cell MC<m, n> due to the spin orbit torque, and suppresses the frustration in the reversal process. As a result, the magnetization direction of the ferromagnetic layer 41 of the selected memory cell MC<m, n> is reversed in a direction antiparallel to the magnetization direction of the ferromagnetic layer 43.

By the above operation, the data “1” is written to the selected memory cell MC<m, n>.

Note that the combined magnetic fields of the magnetic fields Hw0<n>, Hw0<n−1>, and Hw0<n+1> in the first example of the write operation and the combined magnetic fields of the magnetic fields Hw1<n>, Hw1<n−1>, and Hw1<n+1> in the second example of the write operation also act on the unselected memory cells MC<m, n−1> and MC<m, n+1>. However, the magnitude of the combined magnetic field applied to the unselected memory cells MC<m, n−1> and MC<m, n+1> is sufficiently smaller than the magnitude of the magnetic field for reversing the magnetization direction of the ferromagnetic layer 41. Therefore, in both the first example and the second example of the write operation, data is not written to the unselected memory cells MC<m, n−1> and MC<m, n+1>.

### 1.2.3 Current Application Timing

Next, the timing of applying the current to be applied during the write operation will be described. Hereinafter, six application examples that can be applied to both the first example and the second example of the write operation will be described. Hereinafter, for convenience of description, the currents Ic0 and Ic1 are simply referred to as a current Ic. Similarly, the currents Iw0<n> and Iw1<n>, Iw0<n−1> and Iw1<n−1>, and Iw0<n+1> and Iw1<n+1> are simply described as currents Iw<n>, Iw<n−1>, and Iw<n+1>, respectively.

### First Application Example

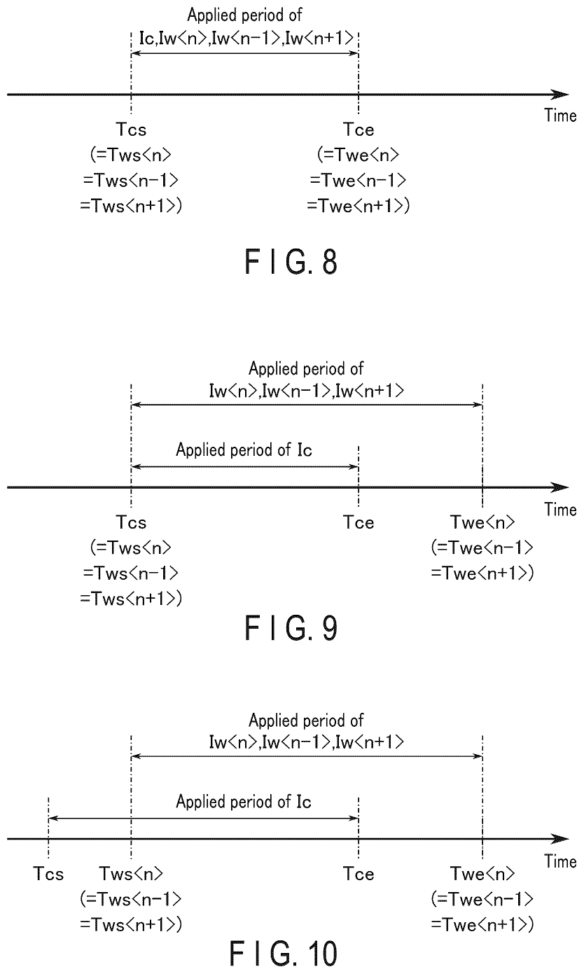

FIG. 8 is a diagram illustrating a first application example of the timing of applying a current to be applied in the write operation of the magnetic memory device in the first embodiment. The first application example corresponds to a case where the application start time of the current Ic substantially coincides with the application start time of each of the currents Iw<n>, Iw<n−1>, and Iw<n+1>, and the application end time of the current Ic substantially coincides with the application end time of each of the currents Iw<n>, Iw<n−1>, and Iw<n+1>.

As illustrated in FIG. 8, the application start time Tcs of the current Ic may substantially coincide with the application start time Tws<n> of the current Iw<n>, the application start time Tws<n−1> of the current Iw<n−1>, and the application start time Tws<n+1> of the current Iw<n+1>. The application end time Tce of the current Ic may substantially coincide with the application end time Twe<n> of the current Iw<n>, the application end time Twe<n−1> of the current Iw<n−1>, and the application end time Twe<n+1> of the current Iw<n+1>.

### Second Application Example

FIG. 9 is a diagram illustrating a second application example of the timing of applying the current applied in the write operation of the magnetic memory device in the first embodiment. The second application example corresponds to a case where the application start time of the current Ic substantially coincides with the application start time of each of the currents Iw<n>, Iw<n−1>, and Iw<n+1>, and the application end time of the current Ic is different from the application end time of each of the currents Iw<n>, Iw<n−1>, and Iw<n+1>.

As illustrated in FIG. 9, the application start time Tcs of the current Ic may substantially coincide with the application start time Tws<n> of the current Iw<n>, the application start time Tws<n−1> of the current Iw<n−1>, and the application start time Tws<n+1> of the current Iw<n+1>. The application end time Tce of the current Ic may be different from the application end time Twe<n> of the current Iw<n>, the application end time Twe<n−1> of the current Iw<n−1>, and the application end time Twe<n+1> of the current Iw<n+1>.

FIG. 9 illustrates a case where the application of the currents Iw<n>, Iw<n−1>, and Iw<n+1> ends after the application of the current Ic ends, but the second application example is not limited thereto. For example, the second application example may include a case where the application of the current Ic is ended after the application of the currents Iw<n>, Iw<n−1>, and Iw<n+1> is ended. However, from the viewpoint of improving the stability of magnetization reversal of the ferromagnetic layer 41, it is more preferable that the application of the currents Iw<n>, Iw<n−1>, and Iw<n+1> ends after the application of the current Ic ends.

### Third Application Example

FIG. 10 is a diagram showing a third application example of the timing of applying a current to be applied in the write operation of the magnetic memory device in the first embodiment. The third application example corresponds to a case where the application start time of the current Ic is different from the application start time of each of the currents Iw<n>, Iw<n−1>, and Iw<n+1>, and the application end time of the current Ic is different from the application end time of each of the currents Iw<n>, Iw<n−1>, and Iw<n+1>.

As illustrated in FIG. 10, the application start time Tcs of the current Ic may be different from the application start time Tws<n> of the current Iw<n>, the application start time Tws<n−1> of the current Iw<n−1>, and the application start time Tws<n+1> of the current Iw<n+1>. The application end time Tce of the current Ic may be different from the application end time Twe<n> of the current Iw<n>, the application end time Twe<n−1> of the current Iw<n−1>, and the application end time Twe<n+1> of the current Iw<n+1>.

Similarly to FIG. 9, FIG. 10 illustrates a case where the application of the currents Iw<n>, Iw<n−1>, and Iw<n+1> ends after the application of the current Ic ends, but the second application example is not limited thereto. For example, the third application example may include a case where the application of the current Ic is ended after the application of the currents Iw<n>, Iw<n−1>, and Iw<n+1> is ended. However, from the viewpoint of improving the stability of magnetization reversal of the ferromagnetic layer 41, it is more preferable that the application of the currents Iw<n>, Iw<n−1>, and Iw<n+1> ends after the application of the current Ic ends.

### Fourth Application Example

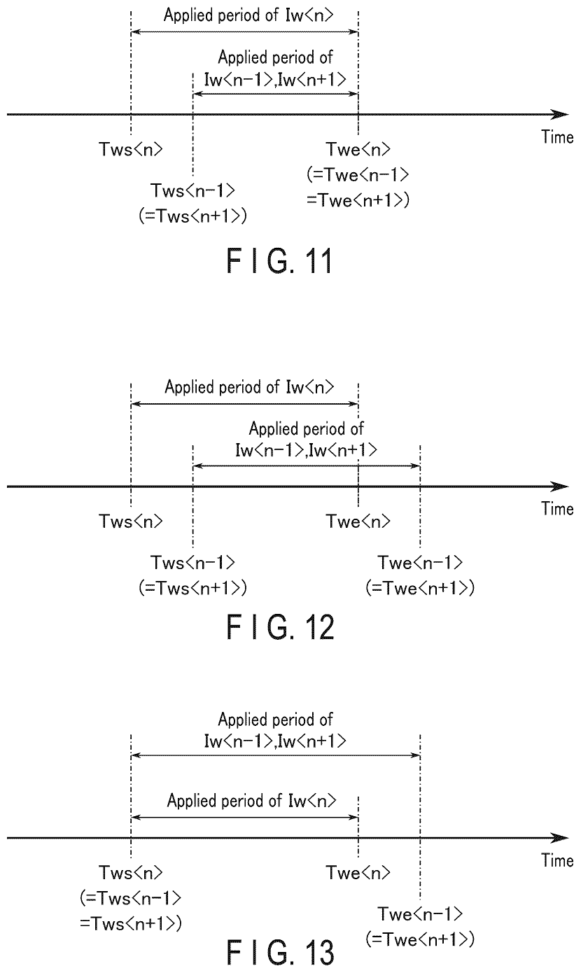

FIG. 11 is a diagram showing a fourth application example of the timing of applying a current to be applied in the write operation of the magnetic memory device in the first embodiment. The fourth application example corresponds to a case where the application start time of the current Iw<n> is different from the application start time of each of the currents Iw<n−1> and Iw<n+1>, and the application end time of the current Iw<n> substantially coincides with the application end time of each of the currents Iw<n−1> and Iw<n+1>.

As illustrated in FIG. 11, the application start time Tws<n> of the current Iw<n> may be different from the application start time Tws<n−1> of the current Iw<n−1> and the application start time Tws<n+1> of the current Iw<n+1>. The application end time Twe<n> of the current Iw<n> may substantially coincide with the application end time Twe<n−1> of the current Iw<n−1> and the application end time Twe<n+1> of the current Iw<n+1>.

FIG. 11 illustrates a case where the application of the currents Iw<n−1> and Iw<n+1> is started after the application of the current Iw<n> is started, but the fourth application example is not limited thereto. For example, the fourth application example may include a case where the application of the current Iw<n> starts after the application of the currents Iw<n−1> and Iw<n+1> starts.

### Fifth Application Example

FIG. 12 is a diagram showing a fifth application example of the timing of applying a current to be applied in the write operation of the magnetic memory device in the first embodiment. The fifth application example corresponds to a case where the application start time of the current Iw<n> is different from the application start time of each of the currents Iw<n−1> and Iw<n+1>, and the application end time of the current Iw<n> is different from the application end time of each of the currents Iw<n−1> and Iw<n+1>.

As illustrated in FIG. 12, the application start time Tws<n> of the current Iw<n> may be different from the application start time Tws<n−1> of the current Iw<n−1> and the application start time Tws<n+1> of the current Iw<n+1>. The application end time Twe<n> of the current Iw<n> may be different from the application end time Twe<n−1> of the current Iw<n−1> and the application end time Twe<n+1> of the current Iw<n+1>.

Similarly to FIG. 11, FIG. 12 illustrates a case where the application of the currents Iw<n−1> and Iw<n+1> is started after the application of the current Iw<n> is started, but the fourth application example is not limited thereto. For example, the fourth application example may include a case where the application of the current Iw<n> starts after the application of the currents Iw<n−1> and Iw<n+1> starts.

In addition, FIG. 12 illustrates a case where the application of the currents Iw<n−1> and Iw<n+1> ends after the application of the current Iw<n> ends, but the fifth application example is not limited thereto. For example, the fifth application example may include a case where the application of the current Iw<n> ends after the application of the currents Iw<n−1> and Iw<n+1> ends.

### Sixth Application Example

FIG. 13 is a diagram showing a sixth application example of the timing of applying a current to be applied in the write operation of the magnetic memory device in the first embodiment. The sixth application example corresponds to a case where the application start time of the current Iw<n> and the application start time of each of the currents Iw<n−1> and Iw<n+1> substantially coincide with each other, and the application end time of the current Iw<n> and the application end time of each of the currents Iw<n−1> and Iw<n+1> are different from each other.

As illustrated in FIG. 13, the application start time Tws<n> of the current Iw<n> may substantially coincide with the application start time Tws<n−1> of the current Iw<n−1> and the application start time Tws<n+1> of the current Iw<n+1>. The application end time Twe<n> of the current Iw<n> may be different from the application end time Twe<n-1> of the current Iw<n−1> and the application end time Twe<n+1> of the current Iw<n+1>.

In FIG. 13, similarly to FIG. 12, the case where the application of the currents Iw<n−1> and Iw<n+1> ends after the application of the current Iw<n> ends is illustrated, but the fifth application example is not limited thereto. For example, the sixth application example may include a case where the application of the current Iw<n> ends after the application of the currents Iw<n−1> and Iw<n+1> ends.

### 1.3 Effects According to the First Embodiment

According to the first embodiment, the current Ic<m> is applied to the wiring SOTL<m> during the write operation to the magnetoresistance effect element MTJ<m, n>. Then, the currents Iw<n>, Iw<n−1>, and Iw<n+1> are applied to the read bit lines RBL<n>, RBL<n−1>, and RBL<n+1>, respectively, so as to overlap with a period during which the current Ic<m> is applied. As a result, the magnetic fields Hw<n>, Hw<n−1>, and Hw<n+1> can be applied to the vicinity of the interface between the ferromagnetic layer 41 corresponding to the magnetoresistance effect element MTJ<m, n> and the wiring SOTL<m>.

The direction of the magnetic field Hw<n> is parallel to the +X direction. Therefore, the magnetic field Hw<n> can assist the reversal of the magnetization direction of the ferromagnetic layer 41 of the selected memory cell MC<m, n> by the spin orbit torque. The magnetic fields Hw<n−1> and Hw<n+1> have a component in the +Z direction in a case where the magnetization direction of the ferromagnetic layer 41 is inverted in the +Z direction, and have a component in the −Z direction in a case where the magnetization direction of the ferromagnetic layer 41 is inverted in the −Z direction. Therefore, the magnetic fields Hw<n−1> and Hw<n+1> can improve stability when the magnetization direction of the ferromagnetic layer 41 of the selected memory cell MC<m, n> is reversed by the spin orbit torque.

### 2. Second Embodiment

Next, a magnetic memory device according to a second embodiment will be described. The second embodiment is different from the first embodiment in that a wiring SOTL is provided for each memory cell MC. Hereinafter, configurations and operations different from those of the first embodiment will be mainly described. Description of configurations and operations equivalent to those of the first embodiment will be omitted as appropriate.

### 2.1 Memory Cell Array

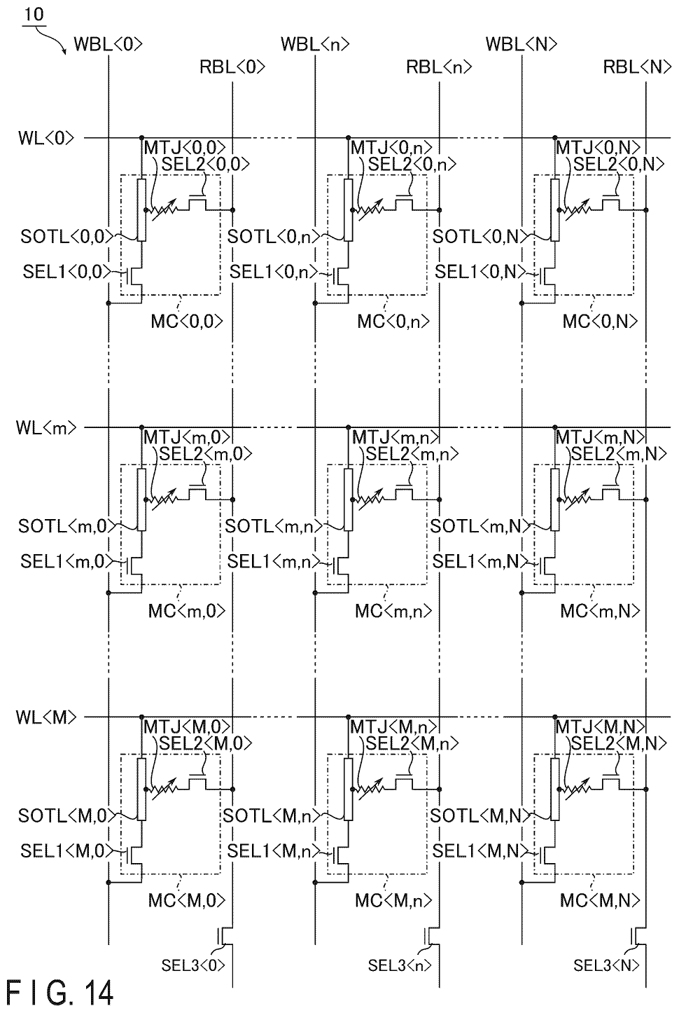

FIG. 14 is a circuit diagram illustrating an example of a circuit configuration of a memory cell array according to a second embodiment; FIG. 14 corresponds to FIG. 2 in the first embodiment.

The memory cell array 10 includes a plurality of word lines WL, a plurality of read bit lines RBL, a plurality of write bit lines WBL, and a plurality of memory cells MC. The memory cell array 10 includes a plurality of switching elements SEL3.

The plurality of switching elements SEL3 has the same configuration as the plurality of switching elements SEL3 in the first embodiment. The plurality of word lines WL include (M+1) word lines WL<0>, . . . , WL<m>, . . . , and WL<M>. The plurality of read bit lines RBL includes (N+1) read bit lines RBL<0>, . . . , RBL<n>, . . . , and RBL<N>. The plurality of write bit lines WBL includes (N+1) write bit lines WBL<0>, WBL<n>, . . . and WBL<N>. The plurality of switching elements SEL3 includes (N+1) switching elements SEL3<0>, . . . , and SEL3<N>. The plurality of memory cells MC includes (M+1)×(N+1) memory cells MC<0, 0>, . . . , MC<0, n>, . . . , MC<0, N>, . . . , MC<m, 0>, . . . , MC<m, n>, MC<m, N>, . . . , MC<M, 0>, . . . , MC<M, n>, . . . , and MC<M, N>. The memory cells MC<0, 0> to MC<M, N> have the same configuration. Hereinafter, the memory cell MC<m, n> and the word line WL<m>, the read bit line RBL<n>, and the write bit line WBL<n> connected to the memory cell MC<m, n> will be described as examples.

The memory cell MC<m, n> includes switching elements SEL1<m, n> and SEL2<m, n>, a wiring SOTL<m, n>, and a magnetoresistance effect element MTJ<m, n>.

The switching element SEL1<m, n> has a first end connected to the wiring SOTL<m, n>, a second end connected to the write bit line WBL<n>, and a control end.

The wiring SOTL<m, n> has a first end connected to the first end of the switching element SEL1<m, n>, a second end connected to the word line WL<m>, and a central portion between both ends. A magnetoresistance effect element MTJ<m, n> is connected to a central portion of the wiring SOTL<m, n>.

The magnetoresistance effect element MTJ<m, n> has a first end connected to the central portion of the wiring SOTL<m, n> and a second end connected to the switching element SEL2<m, n>.

The switching element SEL2<m, n> has a first end connected to the second end of the magnetoresistance effect element MTJ<m, n>, a second end connected to the read bit line RBL<n>, and a control end.

As described above, one memory cell MC includes a set of one wiring SOTL and one magnetoresistance effect element MTJ.

### 2.2 Memory Cell

Next, a configuration of a memory cell of a magnetic memory device according to a second embodiment will be described.

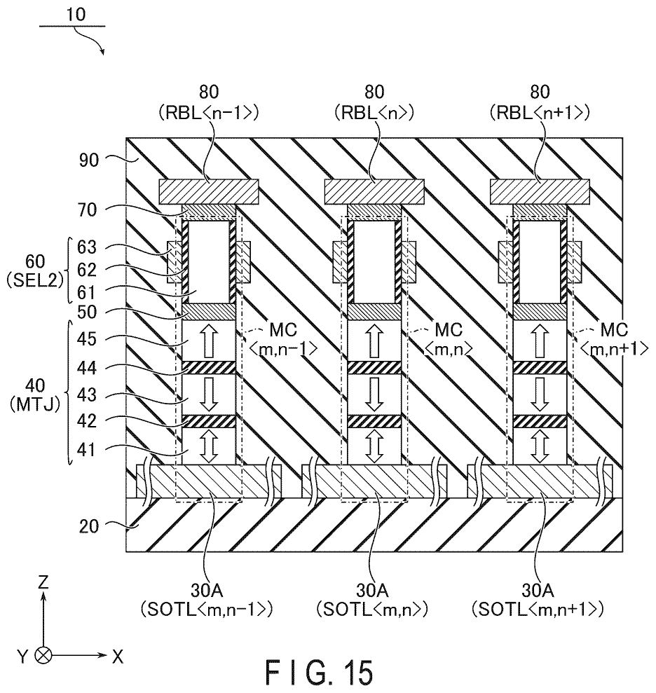

FIG. 15 is a cross-sectional view illustrating an example of a partial cross-sectional structure of the memory cell array according to the second embodiment. FIG. 15 illustrates, as an example, three memory cells MC<m, n−1>, MC<m, n>, and MC<m, n+1> arranged in the X direction. As illustrated in FIG. 15, each of the memory cells MC<m, n>, MC<m, n−1>, and MC<m, n+1> includes a conductor layer 30A, an element layer 40, a conductor layer 50, an element layer 60, a conductor layer 70, and a conductor layer 80.

The cross-sectional structures of the memory cells MC<m, n−1>, MC<m, n>, and MC<m, n+1> in the second embodiment are the same as the cross-sectional structures of the memory cells MC<m, n−1>, MC<m, n>, and MC<m, n+1> in the first embodiment except that a conductor layer 30A used as a wiring SOTL is provided away for each memory cell MC.

That is, the conductor layer 30A<m, n−1>, the conductor layer 30A<m, n>, and the conductor layer 30 A<m, n+1> are arranged apart from each other in the X direction in this order. Each of the conductor layer 30A<m, n−1>, the conductor layer 30 A<m, n>, and the conductor layer 30A<m, n+1> extends in the X direction. A memory cell MC<m, n−1> is provided on the upper surface of the conductor layer 30A<m, n−1>. A memory cell MC<m, n> is provided on the upper surface of the conductor layer 30A<m, n>. A memory cell MC<m, n+1> is provided on the upper surface of the conductor layer 30A<m, n+1>.

### 2.2 Write Operation

Next, a write operation of the magnetic memory device according to the second embodiment will be described.

### 2.2.1 First Example

First, a first example of the write operation will be described.

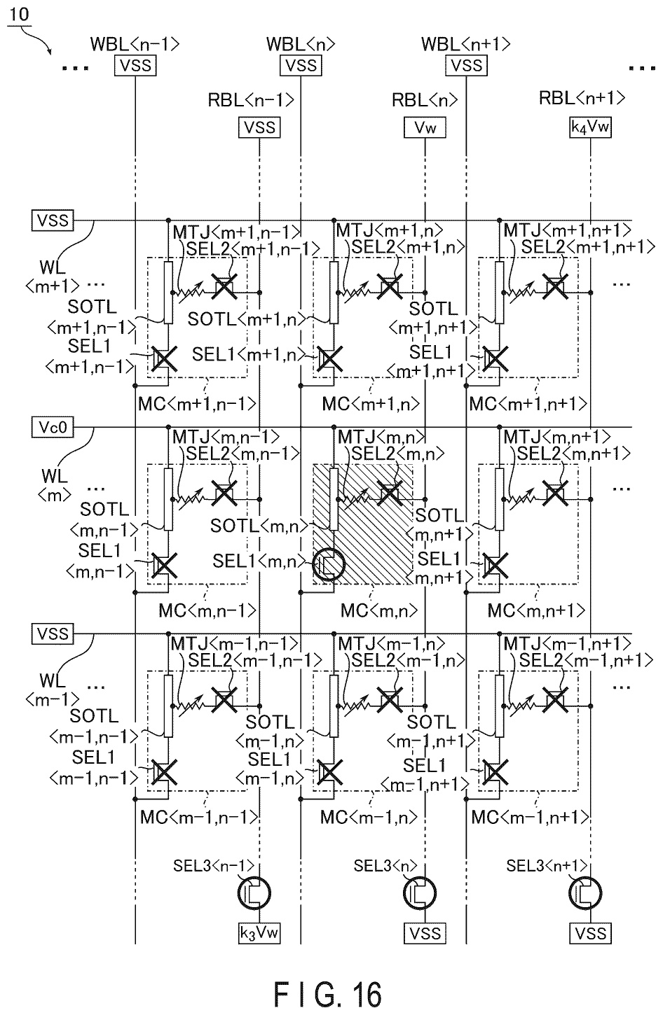

FIG. 16 is a diagram illustrating an example of a voltage applied to the memory cell array in the first example of the write operation in the magnetic memory device according to the second embodiment; FIG. 16 corresponds to FIG. 4 in the first embodiment. FIG. 16 shows an example of voltages applied to three read bit lines RBL<n−1>, RBL<n>, and RBL<n+1>, three write bit lines WBL<n−1>, WBL<n>, and WBL<n+1>, and three word lines WL<m-1>, WL<m>, and WL<m+1> in the memory cell array 10. In FIG. 16, “o” is attached to each of the switching elements SEL1, SEL2, and SEL3 in the ON state, and “×” is attached to each of the switching elements SEL1, SEL2, and SEL3 in the OFF state. In FIG. 16, a memory cell MC<m, n> as a write target (that is, the selected state) is hatched.

In a case where the first example of the write operation is executed for the selected memory cell MC<m, n>, the switching element SEL1<m, n> is turned on. Then, all the switching elements SEL1 except the switching element SEL1<m, n> are turned off. All the switching elements SEL2 are turned off. The switching elements SEL3<n−1>, SEL3<n>, and SEL3<n+1> are turned on. Then, all the other switching elements SEL3 are turned off.

The voltage Vc0 is applied to the word line WL<m>. Then, the voltage VSS is applied to the other word lines WL including the word lines WL<m−1> and WL<m+1>. In addition, the voltage VSS is applied to all the write bit lines WBL. As a result, the voltages Vc0 and VSS are applied to both ends of the wiring SOTL<m, n>, respectively.

The voltages VSS and Vw are applied to the first end and the second end of the selected bit line RBL<n>, respectively. The voltages k₃Vw and VSS are applied to the first end and the second end of the unselected bit line RBL<n−1> located on one of both sides of the selected bit line RBL<n>, respectively. The voltage k₃Vw is a voltage k₃ times the voltage Vw (k₃ is a positive real number). The voltages VSS and k₄Vw are applied to the first end and the second end of the unselected bit line RBL<n+1> located on the other of both sides of the selected bit line RBL<n>, respectively. The voltage k₄Vw is a voltage that is k₄ times the voltage Vw (k₄ is a positive real number). Note that k₃ and k₄ may be different from or equal to each other.

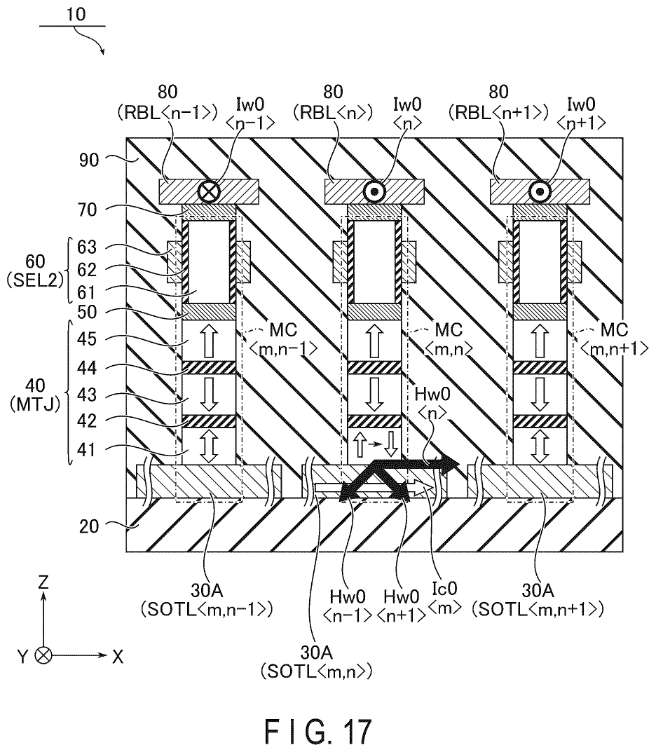

FIG. 17 is a diagram illustrating an example of a current and a magnetic field applied to the memory cell array in the first example of the write operation in the magnetic memory device according to the second embodiment; FIG. 17 corresponds to FIG. 5 in the first embodiment.

As described above, the voltages Vc0 and VSS are applied to both ends of the wiring SOTL<m, n>, respectively. As a result, a write current Ic0<m> flows from the left side of the conductor layer 30A corresponding to the selected memory cell MC<m, n> to the right side of the sheet (+X direction in FIG. 17). When the write current Ic0<m> flows in the conductor layer 30 A corresponding to the selected memory cell MC<m, n>, spin orbit torque is generated to make the magnetization direction of the ferromagnetic layer 41 corresponding to the selected memory cell MC<m, n> parallel to the ferromagnetic layer 43 corresponding to the selected memory cell MC<m, n>.

Further, as described above, the voltages VSS and Vw are applied to both ends of the selected bit line RBL<n>, respectively. Voltages k₃Vw and VSS are applied to both ends of the unselected bit line RBL<n−1>, respectively. The voltages VSS and k₄Vw are applied to both ends of the unselected bit line RBL<n+1>, respectively. As a result, a current Iw0<n> flows in the conductor layer 80 corresponding to the selected bit line RBL<n> from the back side of the page toward the front side of the page (−Y direction in FIG. 17). In the conductor layer 80 corresponding to the unselected bit line RBL<n−1>, a current Iw0<n−1> flows from the front side to the far side (+Y direction in FIG. 17) in the drawing. In the conductor layer 80 corresponding to the selected bit line RBL<n+1>, a current Iw0<n+1> flows from the back side of the page toward the front side of the page (−Y direction in FIG. 17). The currents Iw0<n−1> and Iw0<n+1> in the second embodiment are, for example, k₃ times and k₄ times the current Iw0<n>, respectively. That is, the current values of the currents Iw0<n−1> and Iw0<n+1> in the second embodiment may be smaller or larger than the current value of the current Iw0<n>.

Due to the currents Iw0<n>, Iw0<n−1>, and Iw0<n+1>, magnetic fields Hw0<n>, Hw0<n−1>, and Hw0<n+1> are applied to the vicinity of the interface between the conductor layer 30 A corresponding to the selected memory cell MC<m, n> and the ferromagnetic layer 41 corresponding to the selected memory cell MC<m, n>, respectively.

The magnitude and direction of the current Ic0 and the magnitude and direction of each of the magnetic fields Hw0<n>, Hw0<n−1>, and Hw0<n+1> are the same as those in the first embodiment. Therefore, the data “0” is written to the selected memory cell MC<m, n>.

### 2.2.2 Second Example

Next, a second example of the write operation will be described.

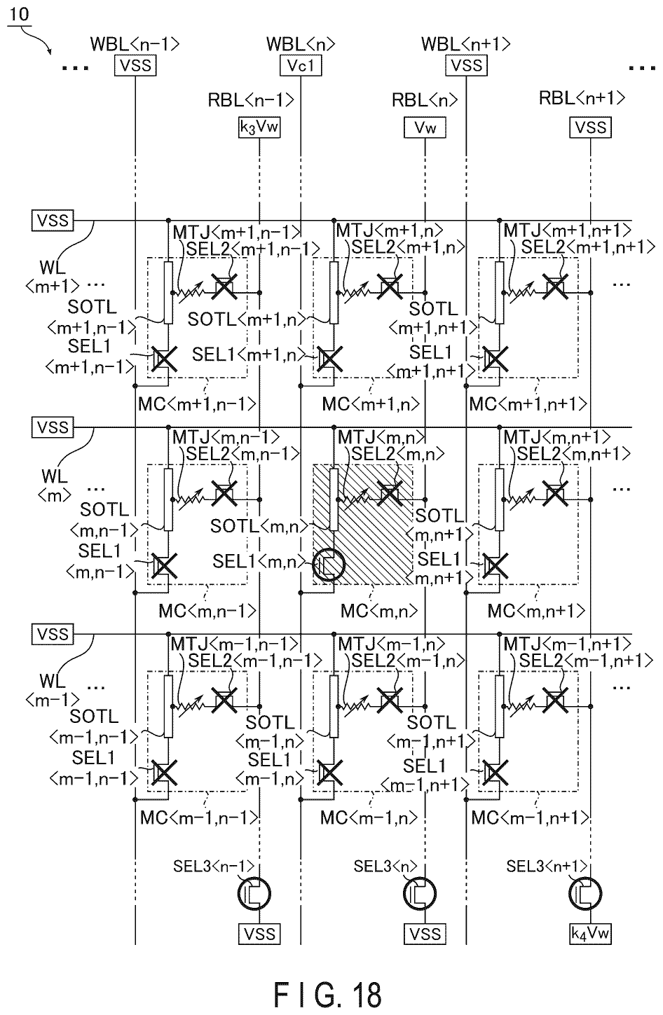

FIG. 18 is a diagram illustrating an example of a voltage applied to the memory cell array in the second example of the write operation in the magnetic memory device according to the second embodiment; FIG. 18 corresponds to FIG. 16 in the first example of the write operation.

When the second example of the write operation is executed for the selected memory cell MC<m, n>, the switching element SEL1<m, n> is turned on. Then, all the switching elements SEL1 except the switching element SEL1<m, n> are turned off. All the switching elements SEL2 are turned off. The switching elements SEL3<n−1>, SEL3<n>, and SEL3<n+1> are turned on. Then, all the other switching elements SEL3 are turned off.

The voltage Vc1 is applied to the write bit line WBL<n>. Then, the voltage VSS is applied to the other write bit lines WBL including the write bit lines WBL<n−1> and WBL<n+1>. In addition, the voltage VSS is applied to all the word lines WL. As a result, the voltages VSS and Vc1 are applied to both ends of the wiring SOTL<m, n>, respectively.

The voltages VSS and Vw are applied to the first end and the second end of the selected bit line RBL<n>, respectively. The voltages VSS and k₃Vw are applied to the first end and the second end of the unselected bit line RBL<n−1>, respectively. The voltages k₄Vw and VSS are applied to the first end and the second end of the unselected bit line RBL<n+1>, respectively. As described above, similarly to the first embodiment, the voltage applied to the selected bit line RBL<n> in the second example of the write operation in the second embodiment is equivalent to the voltage applied to the selected bit line RBL<n> in the first example of the write operation in the second embodiment. On the other hand, the polarities of the voltages applied to the unselected bit lines RBL<n−1> and RBL<n+1> in the second example of the write operation in the second embodiment are inverted from the polarities of the voltages applied to the unselected bit lines RBL<n−1> and RBL<n+1> in the first example of the write operation in the second embodiment.

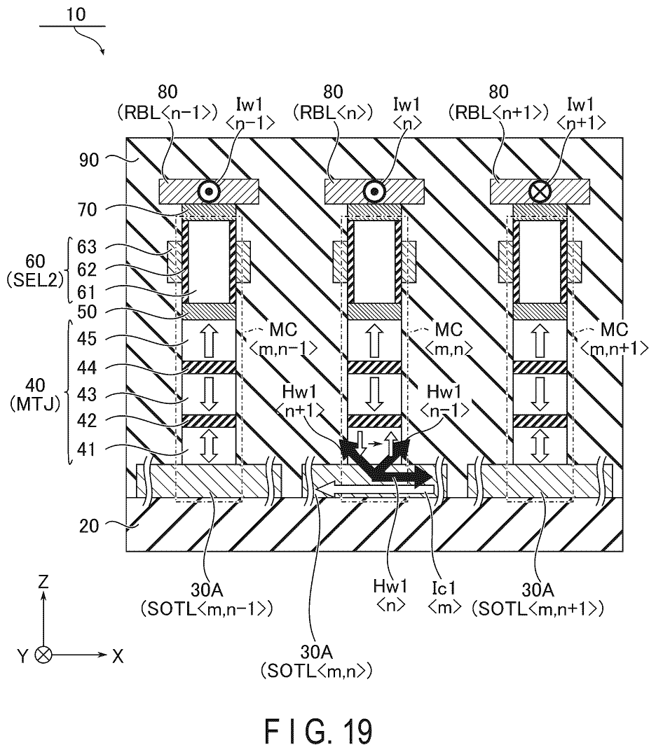

FIG. 19 is a diagram illustrating an example of a current and a magnetic field applied to the memory cell array in the second example of the write operation in the magnetic memory device according to the second embodiment; FIG. 19 corresponds to FIG. 17 in the first example of the write operation.

As described above, the voltages VSS and Vc1 are applied to both ends of the wiring SOTL<m, n>, respectively. As a result, a write current Ic1<m> flows from the right side of the conductor layer 30A corresponding to the selected memory cell MC<m, n> to the left side (−X direction in FIG. 19). When the write current Ic1<m> flows in the conductor layer 30 A corresponding to the selected memory cell MC<m, n>, spin orbit torque is generated to make the magnetization direction of the ferromagnetic layer 41 corresponding to the selected memory cell MC<m, n> antiparallel to the ferromagnetic layer 43 corresponding to the selected memory cell MC<m, n>.

Further, as described above, the voltages VSS and Vw are applied to both ends of the selected bit line RBL<n>, respectively. The voltages VSS and k₃Vw are applied to both ends of the unselected bit line RBL<n−1>, respectively. The voltages k₄Vw and VSS are applied to both ends of the unselected bit line RBL<n+1>, respectively. As a result, a current Iw1<n> flows in the conductor layer 80 corresponding to the selected bit line RBL<n> from the back side of the page toward the front side of the page (−Y direction in FIG. 19). In the conductor layer 80 corresponding to the unselected bit line RBL<n−1>, a current Iw1<n−1> flows from the back side of the page toward the front side of the page (−Y direction in FIG. 19). In the conductor layer 80 corresponding to the selected bit line RBL<n+1>, a current Iw1<n+1> flows from the front side to the far side (+Y direction in FIG. 19).

Due to the currents Iw1<n>, Iw1<n−1>, and Iw1<n+1>, magnetic fields Hw1<n>, Hw1<n−1>, and Hw1<n+1> are applied to the vicinity of the interface between the conductor layer 30 A corresponding to the selected memory cell MC<m, n> and the ferromagnetic layer 41 corresponding to the selected memory cell MC<m, n>, respectively.

The magnitude and direction of the current Ic1 and the magnitude and direction of each of the magnetic fields Hw1<n>, Hw1<n−1>, and Hw1<n+1> are the same as those in the first embodiment. Therefore, the data “1” is written to the selected memory cell MC<m, n>.

### 2.3 Effects According to Second Embodiment

According to the second embodiment, the current Ic<m> is applied to the wiring SOTL<m, n> during the write operation to the magnetoresistance effect element MTJ<m, n>. Then, the currents Iw<n>, Iw<n−1>, and Iw<n+1> are applied to the read bit lines RBL<n>, RBL<n−1>, and RBL<n+1>, respectively, so as to overlap with a period during which the current Ic<m> is applied. As a result, the magnetic fields Hw<n>, Hw<n−1>, and Hw<n+1> can be applied in the same direction and magnitude as those of the first embodiment in the vicinity of the interface between the ferromagnetic layer 41 corresponding to the magnetoresistance effect element MTJ<m, n> and the wiring SOTL<m, n>. Therefore, similarly to the first embodiment, the magnetic field Hw<n> can assist the reversal of the magnetization direction of the ferromagnetic layer 41 of the selected memory cell MC<m, n> by the spin orbit torque. In addition, the magnetic fields Hw<n−1> and Hw<n+1> can improve stability when the magnetization direction of the ferromagnetic layer 41 of the selected memory cell MC<m, n> is reversed by the spin orbit torque.

In the write operation to the magnetoresistance effect element MTJ<m, n>, no current flows through the wiring SOTL<m, n−1> and SOTL<m, n+1>. Thus, in the second embodiment, in the write operation to the magnetoresistance effect element MTJ<m, n>, there is a low possibility that data is erroneously written to the magnetoresistance effect elements MTJ<m, n−1> and MTJ<m, n+1>. Therefore, the currents Iw<n−1> and Iw<n+1> in the second embodiment may be smaller or larger than the current Iw<n>. Therefore, the restriction of the write operation can be relaxed.

### 3. Modifications and the Like

Note that the first embodiment and the second embodiment described above are not limited to the examples described above, and various modifications can be applied.

In the first embodiment and the second embodiment described above, in the write operation to the magnetoresistance effect element MTJ<m, n>, the case where the current Iw<n−1> is applied to the read bit line RBL<n−1> and the current Iw<n+1> is applied to the read bit line RBL<n+1> has been described, but the present invention is not limited thereto. For example, any one of the currents Iw<n−1> and Iw<n+1> may be applied. Even in such a case, similarly to the first embodiment and the second embodiment described above, the stability when the magnetization direction of the ferromagnetic layer 41 of the selected memory cell MC<m, n> is reversed by the spin orbit torque can be improved.

In the first embodiment and the second embodiment described above, the case where the currents Iw<n−1> and Iw<n+1> are applied in directions antiparallel to each other has been described, but the present invention is not limited thereto. For example, if the following conditions are satisfied, the currents Iw<n−1> and Iw<n+1> may be applied in directions parallel to each other. The condition includes that the combined magnetic field of the magnetic fields Hw<n−1> and Hw<n+1> has a component in the +Z direction when the magnetization direction of the ferromagnetic layer 41 in the magnetoresistance effect element MTJ<m, n> is reversed in the +Z direction, and has a component in the −Z direction when the magnetization direction of the ferromagnetic layer 41 is reversed in the −Z direction. Even in such a case, similarly to the first embodiment and the second embodiment described above, the stability when the magnetization direction of the ferromagnetic layer 41 of the selected memory cell MC<m, n> is reversed by the spin orbit torque can be improved.

In addition, in the first embodiment and the second embodiment described above, the case where the magnetoresistance effect element MTJ has a bottom-free structure in which the ferromagnetic layer 41 is provided below the ferromagnetic layer 43 has been described, but the present invention is not limited thereto. For example, the magnetoresistance effect element MTJ may have a top-free structure in which the ferromagnetic layer 41 is provided above the ferromagnetic layer 43. In this case, the conductor layer 30 is provided above the ferromagnetic layer 41.

In addition, in the first embodiment and the second embodiment described above, the case where the ferromagnetic layer 41 is provided so as to be in contact with the upper surface of the conductor layer 30 has been described, but the present invention is not limited thereto. The ferromagnetic layer 41 may be provided above the conductor layer 30 with an intermediate layer interposed therebetween. The intermediate layer may include, for example, a conductive layer such as copper (Cu) or an insulating layer such as magnesium oxide (MgO). When the magnetoresistance effect element MTJ has a bottom-free structure, the intermediate layer can function as an underlayer of the magnetoresistance effect element MTJ. When the magnetoresistance effect element MTJ has a top-free structure, the intermediate layer can function as a cap layer of the magnetoresistance effect element MTJ.

In the first embodiment and the second embodiment described above, the case where the three-terminal switching element is applied to the switching elements SEL1, SEL2, and SEL3 has been described, but the present invention is not limited thereto. For example, a two-terminal switching element may be applied to the switching elements SEL1, SEL2, and SEL3.

When the voltage applied between the two terminals is less than the threshold voltage Vth, the two-terminal switching element is in a “high resistance” state or an “off” state, for example, an electrically non-conductive state. In a case where the voltage applied between the two terminals is equal to or higher than the threshold voltage Vth, the two-terminal switching element changes to a “low resistance” state or an “on” state, for example, an electrically conductive state. In the two-terminal switching element, regardless of the polarity of the voltage applied between the two terminals (regardless of the direction of the flowing current), it is possible to switch whether to flow or block the current according to the magnitude of the voltage applied to the corresponding memory cell MC.

Even when the two-terminal switching element is applied to the switching elements SEL2 and SEL3, the stability of the write operation can be improved by using the combined magnetic field of the magnetic fields Hw<n>, Hw<n−1>, and Hw<n+1> as in the case where the three-terminal switching element is applied.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

### REFERENCE SIGNS LIST

1 Magnetic memory device
10 Memory cell array
11 Row selection circuit
12 Column selection circuit
13 Decode circuit
14 Write circuit
15 Read circuit
16 Voltage generation circuit
17 Input/output circuit
18 Control circuit
20, 90 Insulator layer
30, 30A, 50, 63, 70, 80 Conductor layer
40, 60 Element layer
41, 43, 45 Ferromagnetic layer
42, 44 Nonmagnetic layer
61 Semiconductor film
62 Insulator film

What is claimed is:

1. A magnetic memory device comprising:
a first conductor layer extending in a first direction;
a second conductor layer extending in the first direction and arranged with the first conductor layer in a second direction intersecting the first direction;
a first magnetoresistance effect element electrically connected to the first conductor layer;
a second magnetoresistance effect element electrically connected to the second conductor layer; and
a third conductor layer extending in the second direction and in contact with the first magnetoresistance effect element, wherein
in a write operation of writing data to the first magnetoresistance effect element,
a first current is applied to the first conductor layer,
a second current is applied to the second conductor layer, and
a third current is applied to the third conductor layer independently of the first current and the second current.

2. The magnetic memory device according to claim 1, further comprising:
a fourth conductor layer extending in the first direction and arranged with the first conductor layer in the second direction on a side opposite to the second conductor layer with respect to the first conductor layer; and
a third magnetoresistance effect element connected to the fourth conductor layer, wherein
in the write operation,
a fourth current is applied to the fourth conductor layer.

3. The magnetic memory device according to claim 2, wherein
the second magnetoresistance effect element and the third magnetoresistance effect element are adjacent to the first magnetoresistance effect element in the second direction.

4. The magnetic memory device according to claim 2, wherein
a direction of the second current is antiparallel to a direction of the fourth current.

5. The magnetic memory device according to claim 1, wherein
a magnetic field applied to the first magnetoresistance effect element based on the first current and the second current includes a component in the second direction and a component in a third direction intersecting the first direction and the second direction.

6. The magnetic memory device according to claim 1, wherein
the third conductor layer is further in contact with the second magnetoresistance effect element.

7. The magnetic memory device according to claim 1, wherein the second current is smaller than the first current.

8. The magnetic memory device according to claim 1, further comprising
a fifth conductor layer extending in the second direction and in contact with the second magnetoresistance effect element.

9. The magnetic memory device according to claim 1, wherein
the first magnetoresistance effect element includes:
a first ferromagnetic layer in contact with the third conductor layer;
a second ferromagnetic layer; and
a nonmagnetic layer between the first ferromagnetic layer and the second ferromagnetic layer.

10. The magnetic memory device according to claim 9, wherein
a magnetization direction of the first ferromagnetic layer changes from a third direction intersecting the first direction and the second direction to a fourth direction antiparallel to the third direction by the write operation, and
a magnetic field generated based on the second current has a component antiparallel to the third direction and parallel to the fourth direction.

11. The magnetic memory device according to claim 1, wherein
the third conductor layer contains at least one element selected from tantalum (Ta), tungsten (W), rhenium (Re), ruthenium (Ru), rhodium (Rh), palladium (Pd), silver (Ag), copper (Cu), osmium (Os), iridium (Ir), platinum (Pt), gold (Au), manganese (Mn), lead (Pb), bismuth (Bi), antimony (Sb), tellurium (Te), selenium (Se), and polonium (Po).

12. The magnetic memory device according to claim 1, wherein
a first time at which the application of the first current is started and a second time at which the application of the second current is started substantially coincide with a third time at which the application of the third current is started, and
a fourth time at which the application of the first current ends and a fifth time at which the application of the second current ends substantially coincide with a sixth time at which the application of the third current ends.

13. The magnetic memory device according to claim 1, wherein
a first time at which the application of the first current is started and a second time at which the application of the second current is started substantially coincide with a third time at which the application of the third current is started, and
a fourth time at which the application of the first current ends and a fifth time at which the application of the second current ends are different from a sixth time at which the application of the third current ends.

14. The magnetic memory device according to claim 1, wherein
a first time at which the application of the first current is started and a second time at which the application of the second current is started are different from a third time at which the application of the third current is started, and
a fourth time at which the application of the first current ends and a fifth time at which the application of the second current ends are different from a sixth time at which the application of the third current ends.

15. The magnetic memory device according to claim 1, wherein
a first time at which the application of the first current is started is different from a second time at which the application of the second current is started, and
a fourth time at which the application of the first current ends substantially coincides with a fifth time at which the application of the second current ends.

16. The magnetic memory device according to claim 1, wherein
a first time at which the application of the first current is started is different from a second time at which the application of the second current is started, and
a fourth time at which the application of the first current ends is different from a fifth time at which the application of the second current ends.

17. The magnetic memory device according to claim 1, wherein
a first time at which the application of the first current is started substantially coincides with a second time at which the application of the second current is started, and
a fourth time at which the application of the first current ends is different from a fifth time at which the application of the second current ends.
